(19) United States
(12) Patent Application Publication
(10) Pub. No.: US 2026/0264265 A1
(43) Pub. Date: Sep. 10, 2026

(54) SYSTEM AND METHOD FOR MOUNTING PROTECTIVE MEMBER OF SOLAR PANEL

(71) Applicant: Hanwha Solutions Corporation, Seoul (KR)

(72) Inventors: Jun Bae LEE, Seoul (KR); Jin Uk CHOI, Seoul (KR)

(21) Appl. No.: 19/491,394

(22) PCT Filed: Jun. 4, 2024
(86) PCT No.: PCT/KR2024/007657

§ 371 Date: Jan. 16, 2026

(30) Foreign Application Priority Data
Jun. 9, 2023 (KR) 10-2023-0074323

(51) Int. Cl. B25J 15/00; B25J 5/02; H02S 30/00

(52) U.S. Cl. CPC B25J 15/0033; B25J 5/02; H02S 30/00

(57) ABSTRACT

Provided is a system for mounting a protective element of a photovoltaic panel. A system for mounting a protective element of a photovoltaic panel includes a photovoltaic panel transport device configured to transport the photovoltaic panel, a protective element housing device configured to house a plurality of protective elements that protect a corner of the photovoltaic panel, a protective element transport device configured to transport the protective elements, and a protective element insertion device configured to receive the protective elements by the protective element transport device and insert the protective element into the corner of the photovoltaic panel.

### TECHNICAL FIELD

The present disclosure relates to a system and method of mounting a protective element of a photovoltaic panel, and more particularly, to a system and method of mounting a protective element of a photovoltaic panel that automatically mounts the protective element on the photovoltaic panel without manual operation by a user.

### BACKGROUND ART

A photovoltaic panel is a flat-panel assembly containing integrated elements that convert light energy into electrical energy. Such photovoltaic panels utilize sunlight that shines onto the ground. Therefore, for efficient power generation, it is important to select an optimal installation site by considering the climate, solar irradiance, solar altitude, and surrounding environment.

Furthermore, it is also very important to safely transport manufactured photovoltaic panels from a manufacturing facility to a selected installation site. To this end, a process of packaging photovoltaic panels into shipping boxes is performed.

Such photovoltaic panels have a problem in that, during a process of being transported to be packed in a shipping box, or even after being packaged in the shipping box, the photovoltaic panels, especially corners of the photovoltaic panels, may be damaged due to external impacts.

### DISCLOSURE OF INVENTION

### Technical Problem

The present disclosure is intended to solve the problem, and a purpose of the present disclosure is to provide a system and method of mounting a protective element of a photovoltaic panel that automatically mounts the protective element on the photovoltaic panel without manual operation by a user.

The objects of the present disclosure are not limited to the above-mentioned objects, and other objects not mentioned may be clearly understood by a person skilled in the art from the specification described below.

### Solution to Problem

According to an aspect of the present disclosure, a system for mounting a protective element of a photovoltaic panel includes a photovoltaic panel transport device configured to transport the photovoltaic panel, a protective element housing device configured to house a plurality of protective elements that protect a corner of the photovoltaic panel, a protective element transport device configured to transport the protective elements, and a protective element insertion device configured to receive the protective elements by the protective element transport device and insert the protective elements into the corner of the photovoltaic panel.

### ADVANTAGEOUS EFFECTS OF INVENTION

According to the configuration, a system and method of mounting a protective element of a photovoltaic panel according to an embodiment of the present disclosure transport the protective element and insert the protective element into a corner of the photovoltaic panel, thereby eliminating the need for manual operation by a user and reducing a manufacturing cost of the photovoltaic panel.

In some embodiments, a system and method of mounting a protective element of a photovoltaic panel according to an embodiment of the present disclosure have an advantage of maintaining uniform mounting quality of the protective element on the corner of the photovoltaic panel.

### BRIEF DESCRIPTION OF DRAWINGS

FIG. 1 is a diagram illustrating a system for mounting a protective element of a photovoltaic panel according to an embodiment of the present disclosure.

FIG. 2 is a diagram illustrating a position adjustment of the photovoltaic panel in the system for mounting the protective element of the photovoltaic panel according to an embodiment of the present disclosure.

FIG. 3 is a perspective view illustrating a state in which a protective element transport device of the system for mounting the protective element of the photovoltaic panel according to an embodiment of the present disclosure is moved to grip the protective element.

FIG. 4 is a perspective view illustrating a state in which the protective element transport device of the system for mounting the protective element of the photovoltaic panel according to an embodiment of the present disclosure is gripping the protective element.

FIG. 5 is a perspective view illustrating a state in which the protective element transport device of the system for mounting the protective element of the photovoltaic panel according to an embodiment of the present disclosure transports the protective element to a first protective element insertion device.

FIG. 6 is a perspective view illustrating a state in which the protective element transport device of the system for mounting the protective element of the photovoltaic panel according to an embodiment of the present disclosure transports the protective element to a second protective element insertion device.

FIG. 7 is a perspective view illustrating a protective element insertion device of the system for mounting the protective element of the photovoltaic panel according to an embodiment of the present disclosure.

FIG. 8 is a diagram schematically illustrating a state in which the protective element insertion device of the system for mounting the protective element of the photovoltaic panel according to an embodiment of the present disclosure is gripping the protective element.

FIG. 9 is a perspective view illustrating a state in which the protective element insertion device of the system for mounting the protective element of the photovoltaic panel according to an embodiment of the present disclosure is unfolding the protective element.

FIG. 10 is a diagram schematically illustrating a state in which the protective element insertion device of the system for mounting the protective element of the photovoltaic panel according to an embodiment of the present disclosure is unfolding the protective element.

FIG. 11 is a perspective view illustrating a state in which the protective element insertion device of the system for mounting the protective element of the photovoltaic panel according to an embodiment of the present disclosure is folding the protective element again.

FIG. 12 is a perspective view illustrating a state in which the protective element insertion device of the system for mounting the protective element of the photovoltaic panel according to an embodiment of the present disclosure is unfolding the protective element again.

FIG. 13 is a perspective view schematically illustrating a state in which the protective element insertion device of the system for mounting the protective element of the photovoltaic panel according to an embodiment of the present disclosure pushes a portion of the protective element so as to be folded.

FIG. 14 is a perspective view illustrating a state in which the protective element insertion device of the system for mounting the protective element of the photovoltaic panel according to an embodiment of the present disclosure is transported.

FIG. 15 is a perspective view illustrating a state in which the protective element insertion device of the system for mounting the protective element of the photovoltaic panel according to an embodiment of the present disclosure mounts the protective element on a corner of the photovoltaic panel.

FIG. 16 is a perspective view illustrating a state in which a second push part of the system for mounting the protective element of the photovoltaic panel according to an embodiment of the present disclosure is moved.

FIG. 17 is a perspective view illustrating a state in which the second push part of the system for mounting the protective element of the photovoltaic panel according to an embodiment of the present disclosure pushes a portion of the protective element. FIG. 18 is a perspective view illustrating, in the system for mounting the protective element of the photovoltaic panel according to an embodiment of the present disclosure, a state in which the protective element is mounted on the corner of the photovoltaic panel.

FIG. 19 is a perspective view illustrating a protective element housing device of the system for mounting the protective element of the photovoltaic panel according to an embodiment of the present disclosure.

FIG. 20 is a perspective view illustrating a state in which the protective element transport device of the system for mounting the protective element of the photovoltaic panel according to an embodiment of the present disclosure is gripping one of a plurality of protective elements.

FIG. 21 is a perspective view illustrating a state in which the protective element transport device of the system for mounting the protective element of the photovoltaic panel according to an embodiment of the present disclosure is gripping another one of the plurality of protective elements.

### BEST MODE FOR CARRYING OUT THE INVENTION

According to an aspect of the present disclosure, a system for mounting a protective element of a photovoltaic panel includes a photovoltaic panel transport device configured to transport the photovoltaic panel, a protective element housing device configured to house a plurality of protective elements that protect a corner of the photovoltaic panel, a protective element transport device configured to transport the protective elements, and a protective element insertion device configured to receive the protective elements transported by the protective element transport device and insert the protective element into the corner of the photovoltaic panel.

In some embodiments, the protective element transport device includes a plate, a plate driving part configured to rotate the plate, a first connection part extending from one side of the plate and connected to one of the plurality of protective elements, and a second connection part extending from another side of the plate and connected to another one of the plurality of protective elements, wherein when the plate rotates, one of the first connection part and the second connection part is selectively connected to the plurality of protective elements.

In some embodiments, the protective element insertion device includes a first protective element insertion device configured to receive the one of the plurality of protective elements connected to the first connection part, and a second protective element insertion device positioned apart from the first protective element insertion device and configured to receive the other one of the plurality of protective elements connected to the second connection part.

In some embodiments, the protective element insertion device includes a body part, a rail part configured to move the body part, a grip part configured to grip the protective element, and a push part configured to push a portion of the protective element in a first direction or push the protective element in a second direction that is different from the first direction.

In some embodiments, the grip part includes a contact part in contact with the protective element, a pivoting part configured to pivot the contact part, and a pivoting driving part configured to provide driving force to the pivoting part.

In some embodiments, the contact part includes a first contact part in contact with one side of the protective element, and a second contact part in contact with another side of the protective element, wherein the pivoting part includes a first pivoting part configured to pivot the first contact part, and a second pivoting part configured to pivot the second contact part.

In some embodiments, the first contact part moves closer to or moves away from the second contact part.

In some embodiments, when the first contact part and the second contact part move away from each other, the one side of the protective element maintains a state of being in contact with the first contact part, and another side of the protective element maintains a state of being in contact with the second contact part.

In some embodiments, as the one side of the protective element moves away from another side of the protective element, the protective element may be unfold to correspond to the corner of the photovoltaic panel.

In some embodiments, the push part pushes and folds a portion of an unfolded protective element.

In some embodiments, the push part includes an insertion body part having a shape corresponding to the unfolded protective element, and an insertion driving part configured to reciprocate the insertion body part in the second direction.

In some embodiments, the insertion body part pushes a portion of the unfolded protective element to be in contact with the corner of the photovoltaic panel.

In some embodiments, according to another aspect of the present disclosure, a method of mounting a protective element of a photovoltaic panel that mounts the protective element on a corner of the photovoltaic panel includes transporting a photovoltaic panel; transporting a plurality of protective elements housed in a protective element housing device by a protective element transport device; and receiving the protective elements and inserting the same to a corner of the photovoltaic panel, by a protective element insertion device.

In some embodiments, the inserting a protective element includes a first inserting in which the protective element may be unfold to correspond to the corner of the photovoltaic panel, a second inserting in which a portion of the protective element is pushed and curved, a third inserting in which the protective element is transported to the corner of the photovoltaic panel to wrap the same, and a fourth inserting in which a portion of the protective element is in contact with the corner of the photovoltaic panel.

In some embodiments, the inserting a protective element further includes folding an unfolded protective element after the first inserting.

### Mode for the Invention

Hereinafter, embodiments of the present disclosure will be described in detail with reference to the following drawings, so that a person skilled in the art may easily implement the present disclosure. The present disclosure may be implemented in various other forms and are not limited to the embodiments described herein. In order to clearly explain the present disclosure in the drawings, parts that are not related to the description may be omitted, and the same reference numerals may be used for identical or similar components throughout the specification.

The words and terms used in this description and claims should not be limited to their ordinary or dictionary meanings, but should be interpreted in a way that is consistent with the technical idea of the present disclosure, in accordance with the principles by which the inventor may define terms and concepts to best explain his or her disclosure.

Therefore, the embodiments described in this description and the configurations illustrated in the drawings correspond to a preferred embodiment of the present disclosure and do not represent all of the technical ideas of the present disclosure, and there may be various equivalents and modified examples that may replace the configuration at the time of filing of the present disclosure.

In the present description, it is to be understood that the terms such as “including”, “having”, etc., are intended to indicate the existence of the features, numbers, steps, actions, components, parts or combinations thereof disclosed in the description, and are not intended to preclude the possibility that one or more other features, numbers, steps, actions, components, parts or combinations thereof may exist or may be added.

The presence of an element in/on “front”, “rear”, “upper or above or top” or “lower or below or bottom” of another element includes not only being disposed in/on “front”, “rear”, “upper or above or top” or “lower or below or bottom” directly in contact with other elements, but also cases in which another element being disposed in the middle, unless otherwise specified. In addition, unless otherwise specified, that an element is “connected” to another element includes not only direct connection to each other but also indirect connection to each other.

Hereinafter, a system and method of mounting a protective element of a photovoltaic panel according to an embodiment of the present disclosure may be described with reference to the diagrams.

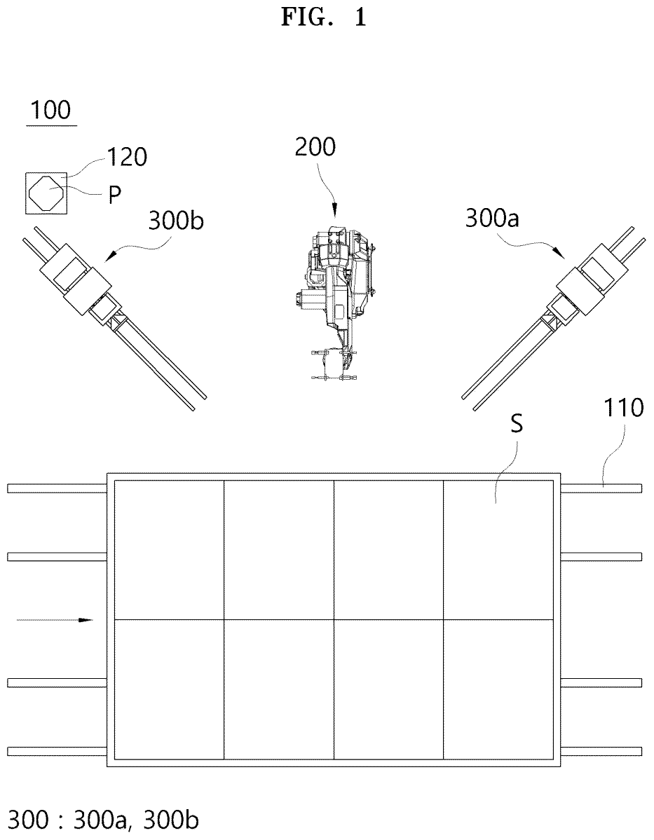

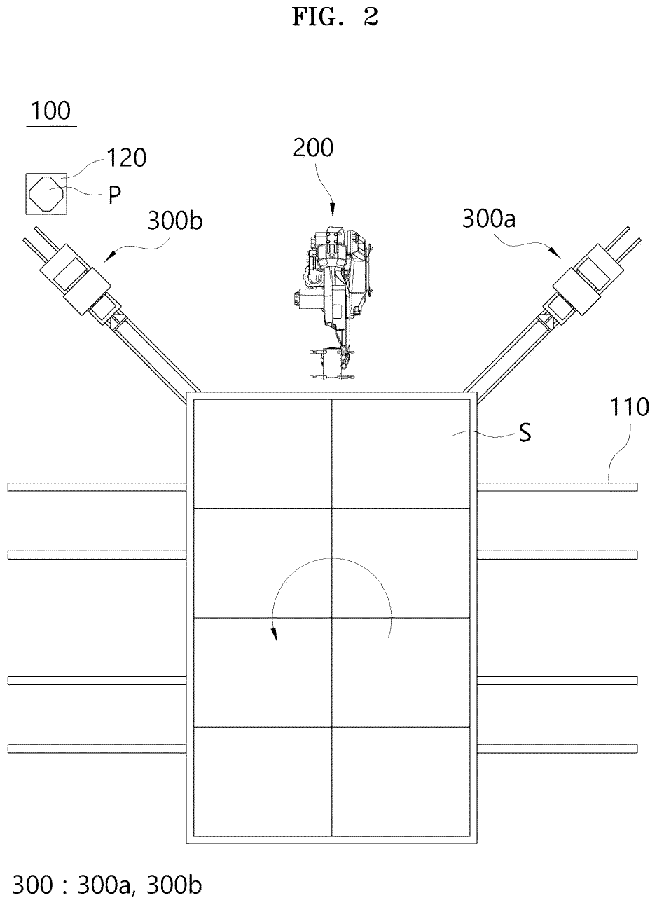

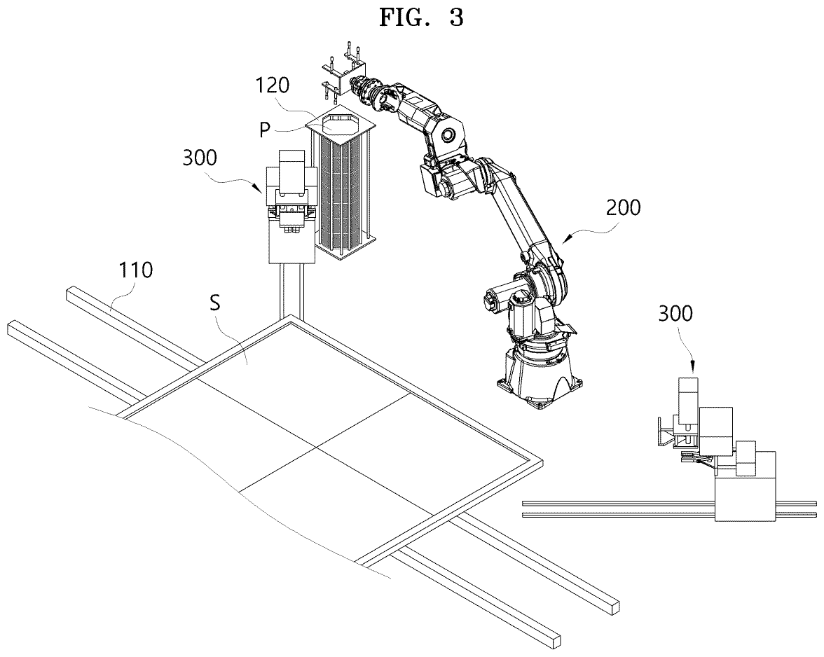

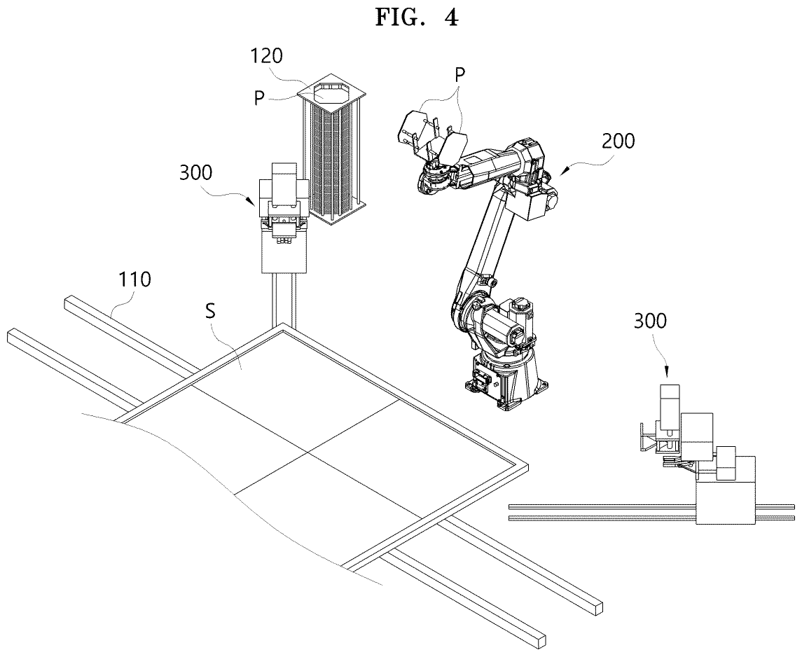

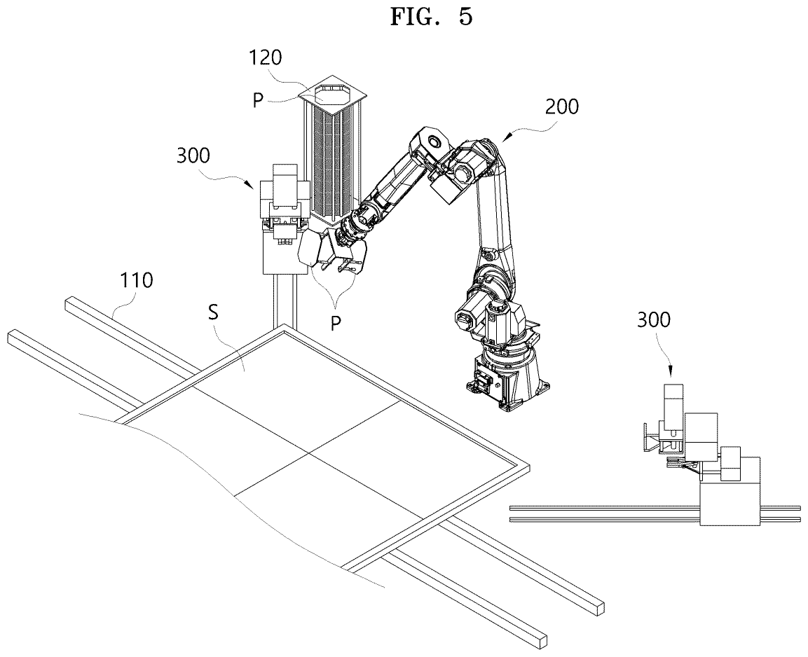

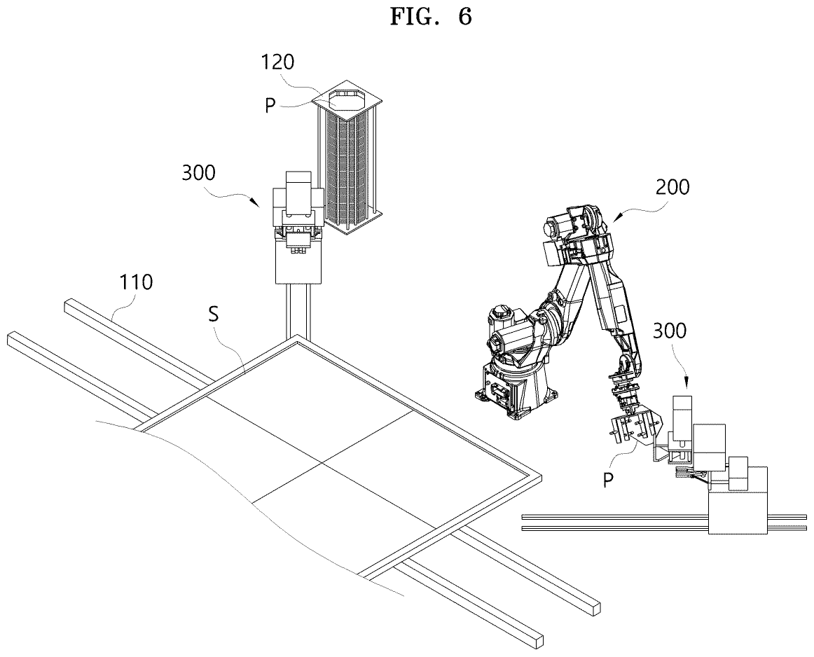

FIG. 1 is a diagram illustrating a system for mounting a protective element of a photovoltaic panel according to an embodiment of the present disclosure, FIG. 2 is a diagram illustrating a position adjustment of the photovoltaic panel in the system for mounting the protective element of the photovoltaic panel according to an embodiment of the present disclosure, FIG. 3 is a perspective view illustrating a state in which a protective element transport device of the system for mounting the protective element of the photovoltaic panel according to an embodiment of the present disclosure is moved to grip the protective element, FIG. 4 is a perspective view illustrating a state in which the protective element transport device of the system for mounting the protective element of the photovoltaic panel according to an embodiment of the present disclosure is gripping the protective element, FIG. 5 is a perspective view illustrating a state in which the protective element transport device of the system for mounting the protective element of the photovoltaic panel according to an embodiment of the present disclosure transports the protective element to a first protective element insertion device, and FIG. 6 is a perspective view illustrating a state in which the protective element transport device of the system for mounting the protective element of the photovoltaic panel according to an embodiment of the present disclosure transports the protective element to a second protective element insertion device.

Referring to FIGS. 1 to 6, a system for mounting a protective element of a photovoltaic panel 100 according to an embodiment of the present disclosure includes a photovoltaic panel transport device 110, a protective element housing device 120, a protective element transport device 200, and a protective element insertion device 300.

The photovoltaic panel transport device 110 transports the photovoltaic panel S. In some embodiments, the photovoltaic panel transport device 110 may include a plurality of rails. In some embodiments, a driving unit (not shown) that provides driving force to transport the photovoltaic panel S is positioned in the photovoltaic panel transport device 110. Accordingly, the photovoltaic panel S is transported in one direction by the photovoltaic panel transport device 110.

In some embodiments, as illustrated in FIG. 2, a rotation part (not shown) configured to rotate the photovoltaic panel S is positioned in the photovoltaic panel transport device 110. In some embodiments, after a protective element P is mounted on a portion of a corner of the photovoltaic panel S, the photovoltaic panel S is rotated by the rotation part so that the protective element P may be mounted on another portion of the corner of the photovoltaic panel S.

A plurality of protective elements that protect the corner of the photovoltaic panel S are housed in the protective element housing device 120. In some embodiments, the protective element housing device 120 is positioned apart from the photovoltaic panel transport device 110 so as not to interfere with the transport of the photovoltaic panel S.

In some embodiments, as illustrated in FIG. 3, the plurality of protective elements P are stacked and housed in the protective element housing device 120 in a folded state. In some embodiments, the plurality of protective elements P include paper material. However, the plurality of protective elements P are not limited to including paper material, and may include various materials that may protect the photovoltaic panel while being folded or unfolded.

The protective element transport device 200 transports the protective element P to the protective element insertion device 300.

First, as illustrated in FIG. 3, the protective element transport device 200 is moved to the protective element housing device 120 to grip the protective element P. In some embodiments, the protective element transport device 200 may be a robot with a multi-joint structure.

In some embodiments, as illustrated in FIG. 4, the protective element transport device 200 grips the plurality of protective elements P.

In some embodiments, as illustrated in FIG. 5, the protective element transport device 200 transports one of the plurality of protective elements P to one of the protective element insertion devices 300.

In some embodiments, as illustrated in FIG. 6, the protective element transport device 200 transports another one of the plurality of protective elements P to another one of the protective element insertion devices 300. The protective element transport device 200 may be described in detail with reference to the diagrams below.

The protective element insertion device 300 receives the protective element P by the protective element transport device 200 and inserts the protective element P into the corner of the photovoltaic panel S.

In some embodiments, the protective element insertion device 300 includes a first protective element insertion device 300a and a second protective element insertion device 300b.

The first protective element insertion device 300a receives one of the plurality of protective elements P connected to the protective element transport device 200.

The second protective element insertion device 300b is positioned on an opposite side of the first protective element insertion device 300a with the protective element transport device 200 positioned therebetween. That is, the second protective element insertion device 300b is positioned apart from the first protective element insertion device 300a. In some embodiments, the second protective element insertion device 300a receives another one of the plurality of protective elements P connected to the protective element transport device 200.

The protective element insertion device 300 may be described with reference to the diagrams below.

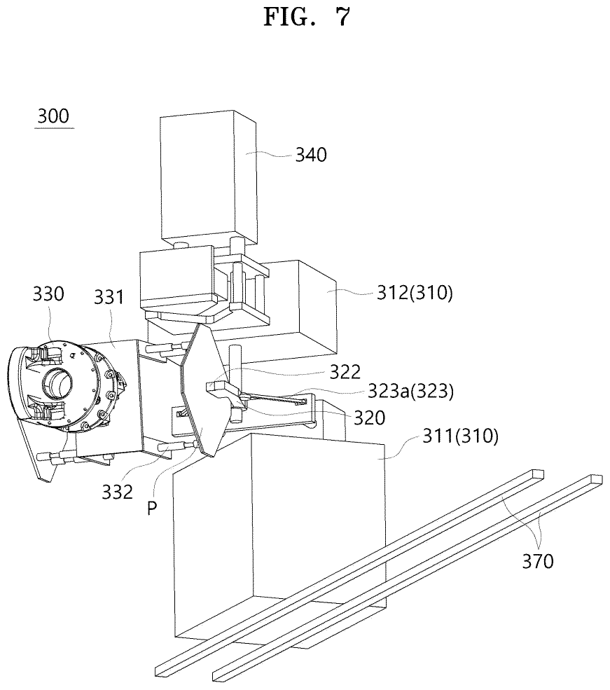

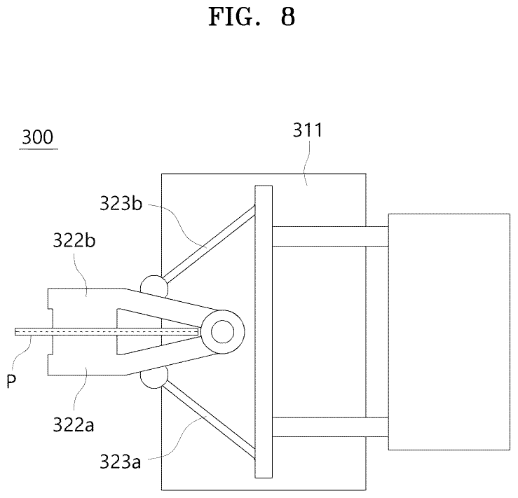

FIG. 7 is a perspective view illustrating a protective element insertion device of the system for mounting the protective element of the photovoltaic panel according to an embodiment of the present disclosure, and FIG. 8 is a diagram schematically illustrating a state in which the protective element insertion device of the system for mounting the protective element of the photovoltaic panel according to an embodiment of the present disclosure is gripping the protective element.

First, as illustrated in FIG. 7, the protective element insertion device 300 includes a body part 310, a rail part 370, and a grip part 320.

The body part 310 supports the grip part 320. In some embodiments, the body part 310 includes a first body part 311 and a second body part 312 positioned on an upper side of the first body part 311.

The rail part 370 moves the first body part 311. In some embodiments, the rail part 370 has a a certain length toward the photovoltaic panel transport device 110 (referring to FIG. 1). In some embodiments, a driving part (not shown) configured to move along the rail part 370 may be positioned on the first body part 311. However, the rail part 370 is not limited to having a certain length, and may have various structures, such as a wheel positioned on the lower side of the first body part 311.

The grip part 320 grips the protective element P. The grip part 320 includes a contact part 322, a pivoting part 323, and a pivoting driving part 330.

The contact part 322 is in contact with the protective element P. In some embodiments, as illustrated in FIG. 8, the contact part 322 includes a first contact part 322a and a second contact part 322b.

The first contact part 322a is in contact with one side of the protective element P. In some embodiments, the first contact part 322a may be in contact with the protective element P by an air suction manner so as to maintain a connection therewith.

The second contact part 322b is positioned symmetrically with the first contact part 322a. In some embodiments, the second contact part 322b is in contact with another side of the protective element P. In some embodiments, the second contact part 322b may be in contact with the protective element P by the air suction manner so as to maintain a connection therewith.

Accordingly, the protective element P is fixed by the first contact part 322a and the second contact part 322b.

The pivoting part 323 pivots the contact part 322. The pivoting part 323 includes a first pivoting part 323a and a second pivoting part 323b.

The first pivoting part 323a pivots the first contact part 322a.

The second pivoting part 323b is positioned symmetrically with the first pivoting part 323a. In some embodiments, the second pivoting part 323b pivots the second contact part 322b. In some embodiments, the second pivoting part 323b is driven simultaneously with the first pivoting part 323a. Accordingly, the first pivoting part 323a and the second pivoting part 323b drive the first contact part 322a and the second contact part 322b to move closer to each other, so that the protective element P is fixed by the first contact part 322a and the second contact part 322b.

The pivoting driving part 330 provides driving force to the pivoting part 323. The pivoting driving part 330 may include an electric motor. In some embodiments, the pivoting driving part 330 provides driving force to the pivoting part 323 through a link 332a supported by the driving body part 331.

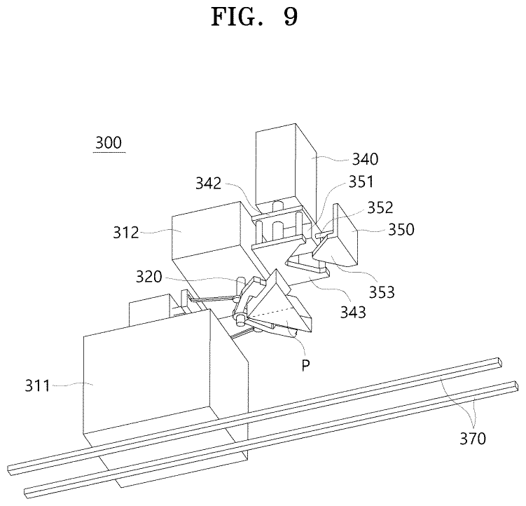

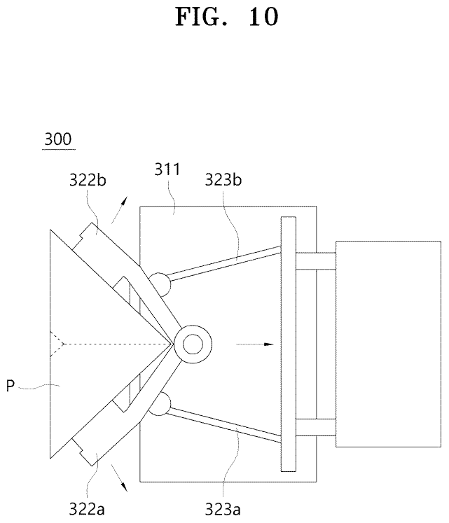

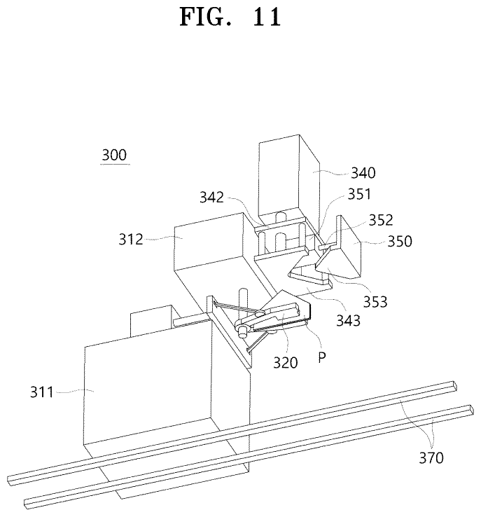

FIG. 9 is a perspective view illustrating a state in which the protective element insertion device of the system for mounting the protective element of the photovoltaic panel according to an embodiment of the present disclosure is unfolding the protective element, FIG. 10 is a diagram schematically illustrating a state in which the protective element insertion device of the system for mounting the protective element of the photovoltaic panel according to an embodiment of the present disclosure is unfolding the protective element, and FIG. 11 is a perspective view illustrating a state in which the protective element insertion device of the system for mounting the protective element of the photovoltaic panel according to an embodiment of the present disclosure is folding the protective element again.

First, as illustrated in FIGS. 9 and 10, when the first pivoting part 323a and the second pivoting part 323b pivot in opposite directions, the first contact part 332a moves away from the second contact part 322b.

In some embodiments, when the first contact part 322a and the second contact part 322b move away from each other, the one side of the protective element P maintains a state of being in contact with the first contact part 322a, and another side of the protective element P maintains a state of being in contact with the second contact part 322b.

In some embodiments, as the one side of the protective element P moves away from another side of the protective element P, the protective element P may be unfold to correspond to the corner of the photovoltaic panel S.

In some embodiments, as illustrated in FIG. 11, according to an embodiment of the present disclosure, when the grip part 320 moves closer to each other, an unfolded protective element P is folded again.

Accordingly, a folded portion of the unfolded protective element P is prevented from protruding outward, and thus, during the process of mounting the protective element P on the corner of the photovoltaic panel S, the protective element P is prevented from being detached from the corner of the photovoltaic panel S.

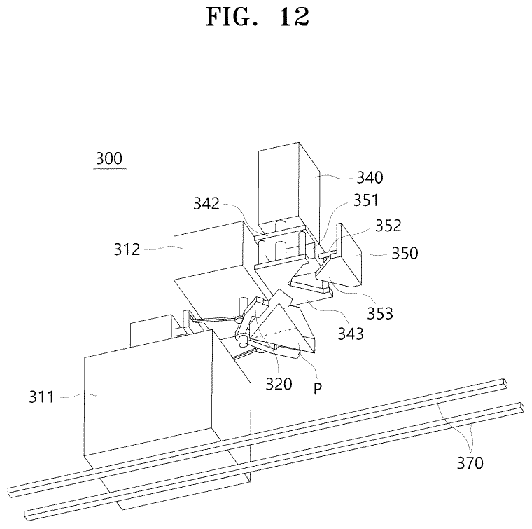

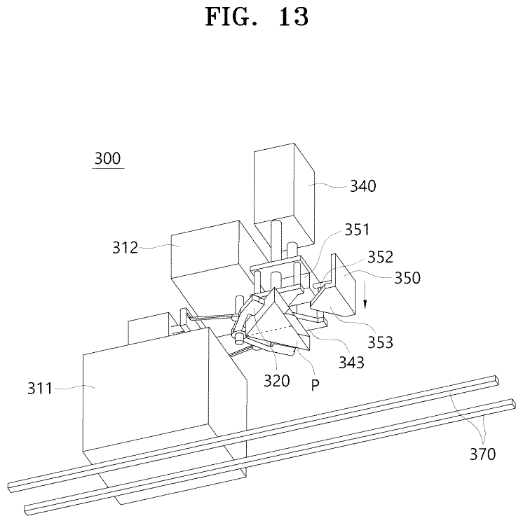

FIG. 12 is a perspective view illustrating a state in which the protective element insertion device of the system for mounting the protective element of the photovoltaic panel according to an embodiment of the present disclosure is unfolding the protective element again, and FIG. 13 is a perspective view schematically illustrating a state in which the protective element insertion device of the system for mounting the protective element of the photovoltaic panel according to an embodiment of the present disclosure pushes a portion of the protective element so as to be folded.

Referring to FIGS. 12 and 13, the protective element insertion device 300 further includes a push part 350 that pushes a portion of the protective element P in a first direction or pushes the protective element P in a second direction that is different from the first direction.

The push part 350 includes a first push driving part 340 that provides a driving force configured to push in the first direction, a push support part 342 that supports the first push driving part 340 while being connected to the second body part 312, a support plate 343 that is connected to the push support part 342, a second push driving part 351 that is connected to the first push driving part 340 and provides a driving force configured to push in the second direction, and an insertion body part 353 that is connected to the second push driving part 351 and has a shape corresponding to the unfolded protective element.

In some embodiments, as illustrated in FIG. 13, when the first push driving part 340 is driven, the insertion body part 353 moves in the first direction toward the protective element P.

In some embodiments, the insertion body part 353 folds a portion of the protective element P. Here, a portion of the protective element P serves to prevent the protective element P from being detached from the corner of the photovoltaic panel S when the protective element P is mounted on the corner of the photovoltaic panel S.

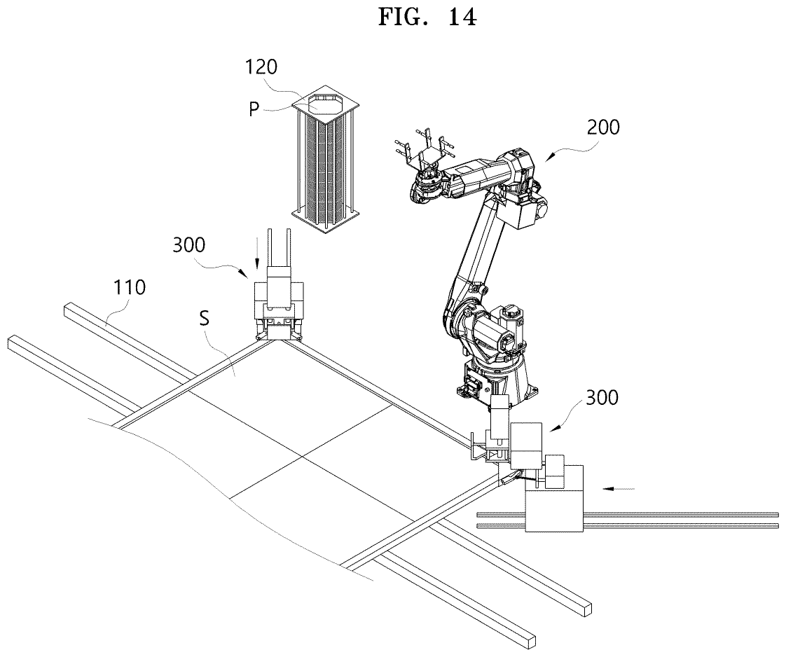

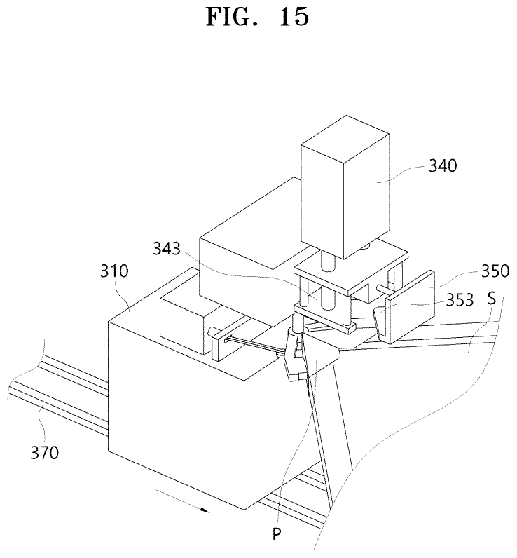

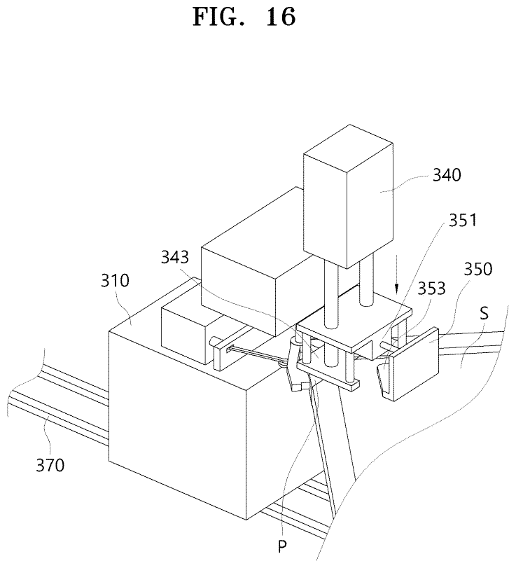

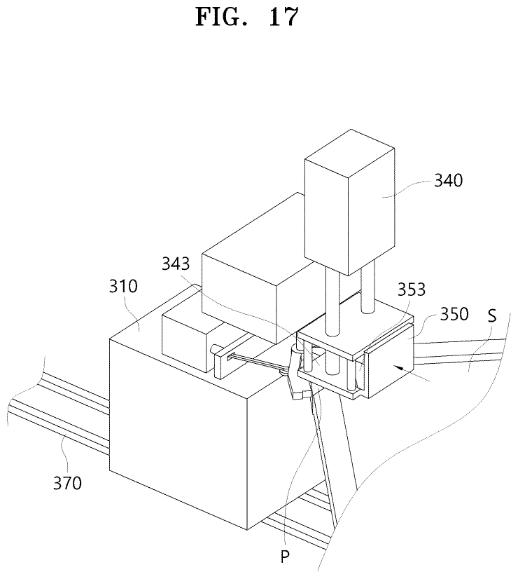

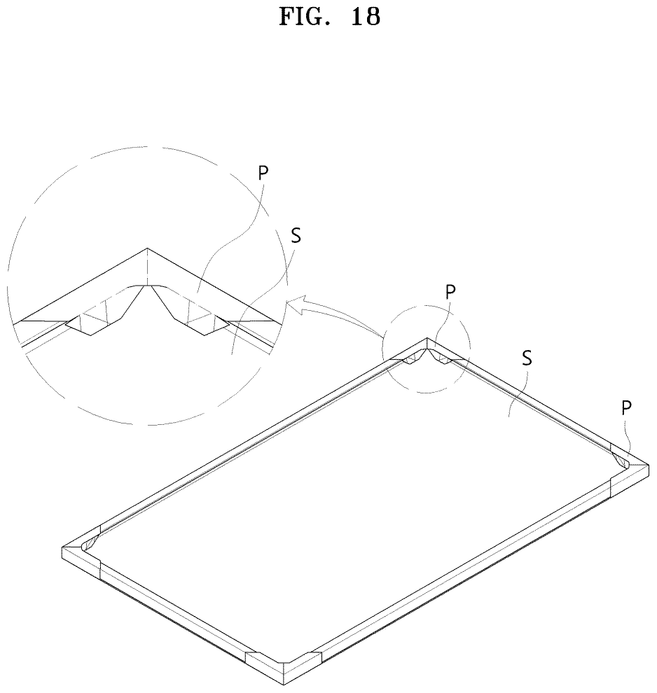

FIG. 14 is a perspective view illustrating a state in which the protective element insertion device of the system for mounting the protective element of the photovoltaic panel according to an embodiment of the present disclosure is transported, FIG. 15 is a perspective view illustrating a state in which the protective element insertion device of the system for mounting the protective element of the photovoltaic panel according to an embodiment of the present disclosure mounts the protective element on a corner of the photovoltaic panel, FIG. 16 is a perspective view illustrating a state in which a second push part of the system for mounting the protective element of the photovoltaic panel according to an embodiment of the present disclosure is moved, FIG. 17 is a perspective view illustrating a state in which the second push part of the system for mounting the protective element of the photovoltaic panel according to an embodiment of the present disclosure pushes a portion of the protective element, and FIG. 18 is a perspective view illustrating, in the system for mounting the protective element of the photovoltaic panel according to an embodiment of the present disclosure, a state in which the protective element is mounted on the corner of the photovoltaic panel.

First, as illustrated in FIGS. 14 and 15, the protective element insertion device 300 approaches the corner of the photovoltaic panel S, and the protective element insertion device 300 mounts the protective element P on the corner of the photovoltaic panel S.

In some embodiments, as illustrated in FIG. 16, the first push driving part 340 moves the insertion body part 353 in the first direction.

In some embodiments, as illustrated in FIG. 17, the second push driving part 351 moves the insertion body part 353 in the second direction.

Accordingly, as illustrated in FIG. 18, a portion of the protective element P is folded and is in contact with the corner of the photovoltaic panel S, thereby preventing the protective element P from being detached from the corner of the photovoltaic panel S.

Accordingly, the device for mounting the protective element of the photovoltaic panel according to an embodiment of the present disclosure automatically mounts the protective element P on the corner of the photovoltaic panel S without manual operation by a user, thereby having the advantage of maintaining uniform mounting quality of the protective element P while reducing the manufacturing cost of the photovoltaic panel S.

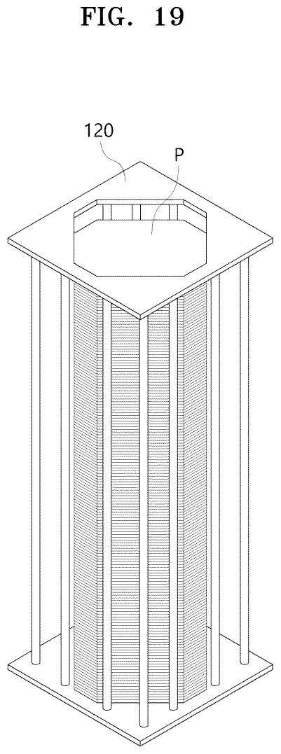

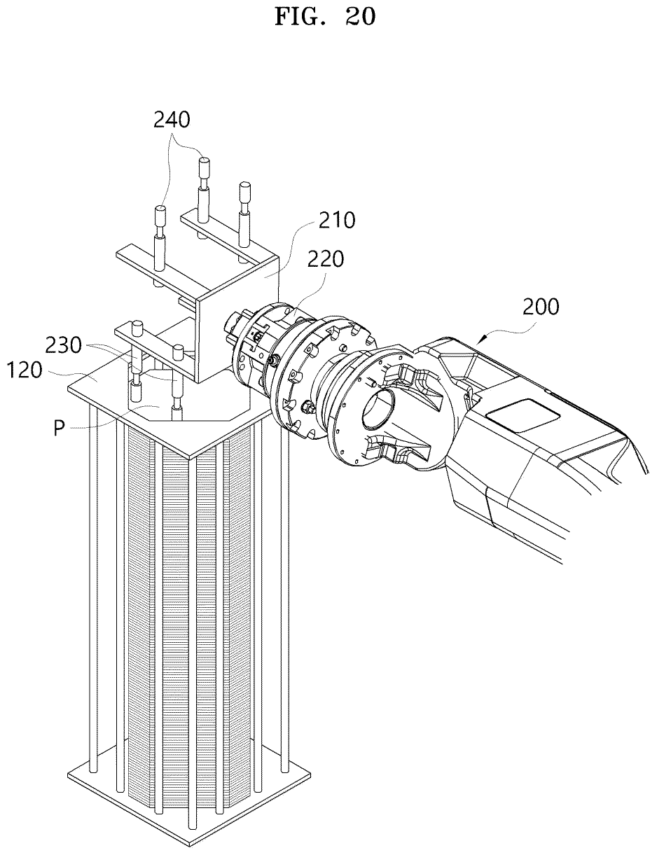

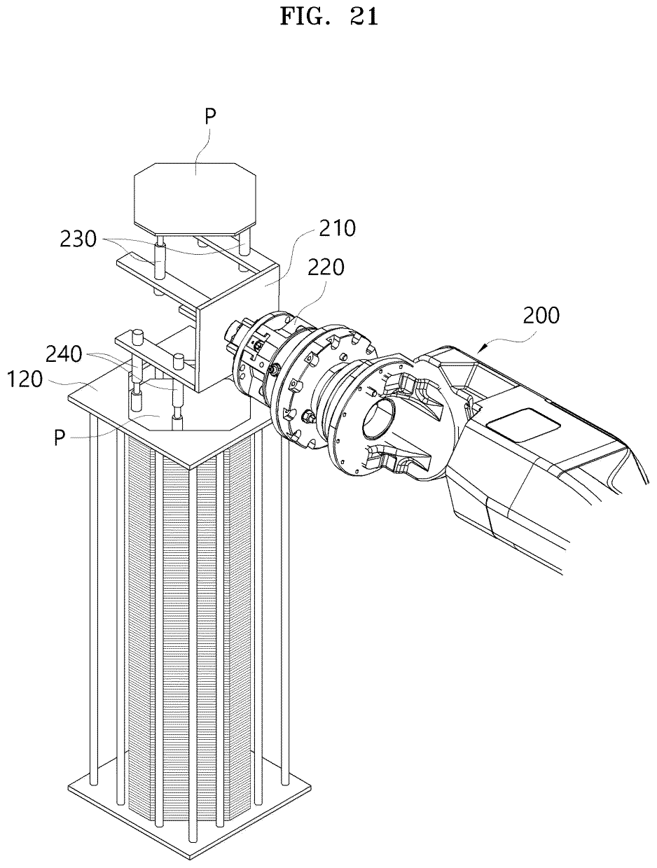

FIG. 19 is a perspective view illustrating a protective element housing device of the system for mounting the protective element of the photovoltaic panel according to an embodiment of the present disclosure, FIG. 20 is a perspective view illustrating a state in which the protective element transport device of the system for mounting the protective element of the photovoltaic panel according to an embodiment of the present disclosure is gripping one of a plurality of protective elements, and FIG. 21 is a perspective view illustrating a state in which the protective element transport device of the system for mounting the protective element of the photovoltaic panel according to an embodiment of the present disclosure is gripping another one of the plurality of protective elements.

First, as illustrated in FIG. 19, the plurality of protective elements P are stacked and accommodated in the protective element housing device 120.

In some embodiments, referring to FIGS. 20 and 21, the protective element transport device 200 includes a plate 210, a plate driving part 220, a first connection part 230, and a second connection part 240.

The plate 210 includes a flat shape. However, the plate 210 is not limited to the flat shape, and may include various shapes such as an oval, or a circle.

The plate driving part 220 is connected to the plate 210 and may rotate the plate 210. The plate driving part 220 may include an electric motor. Accordingly, the plate 210 may be rotated in a clockwise direction or counterclockwise direction by the plate driving part 220.

First, as illustrated in FIG. 20, the first connection part 230 extends from one side of the plate 210 and is connected to one of the plurality of protective elements P. In some embodiments, the first connection part 230 is coupled to one of the plurality of protective elements P in the air suction manner.

In some embodiments, as illustrated in FIG. 21, the second connection part 240 extends from another side of the plate 210, and when the plate 210 is rotated, the second connection part 240 is connected to another one of the plurality of protective elements P. In some embodiments, the second connection part 240 is coupled to another one of the plurality of protective elements P in the air suction manner.

That is, when the plate 210 is rotated, one of the first connection part 230 and the second connection part 240 is selectively connected to the plurality of protective elements P.

In some embodiments, a method of mounting a protective element of a photovoltaic panel according to an embodiment of the present disclosure may include transporting the photovoltaic panel S (referring to FIG. 1), transporting, by a protective element transport device 200, the plurality of protective elements P housed in a protective element housing device 120, and receiving, by the protective element insertion device 200, the protective element P and inserting the same into a corner of the photovoltaic panel S.

In some embodiments, the inserting a protective element may include a first inserting in which the protective element P may be unfold to correspond to the corner of the photovoltaic panel S, a second inserting in which a portion of the protective element P is pushed and curved, a third inserting in which the protective element P is transported to the corner of the photovoltaic panel S and wrapped, and a fourth inserting in which a portion of the protective element P is in contact with the corner of the photovoltaic panel S.

In some embodiments, the inserting a protective element may further include folding an unfolded protective element P after the first inserting.

Accordingly, a method of mounting a protective element of a photovoltaic panel according to an embodiment of the present disclosure has the advantage of automatically mounting the protective element P on the corner of the photovoltaic panel S without manual operation by a user.

Although embodiments of the present disclosure have been described, the technical spirit of the present disclosure is not limited to the embodiments set forth herein, and a person skilled in the art who understands the technical spirit of the present disclosure will readily propose other embodiments through addition, modification, substitution, deletion, or combination of components within the scope of the same technical spirit, and such embodiments also fall within the scope of the technical spirit of the present disclosure.

1. A system for mounting a protective element of a photovoltaic panel, the system comprising:
a photovoltaic panel transport device configured to transport the photovoltaic panel;
a protective element housing device configured to house a plurality of protective elements that protect a corner of the photovoltaic panel;
a protective element transport device configured to transport the protective elements; and
a protective element insertion device configured to receive the protective elements transported by the protective element transport device and insert the protective elements into the corner of the photovoltaic panel.

2. The system for mounting a protective element of a photovoltaic panel of claim 1, wherein the protective element transport device comprises:
a plate;
a plate driving part configured to rotate the plate;
a first connection part extending from one side of the plate and connected to one of the plurality of protective elements; and
a second connection part extending from another side of the plate and connected to another one of the plurality of protective elements,
wherein
when the plate rotates, one of the first connection part and the second connection part is selectively connected to the plurality of protective elements.

3. The system for mounting a protective element of a photovoltaic panel of claim 2, wherein the protective element insertion device comprises:
a first protective element insertion device configured to receive the one of the plurality of protective elements connected to the first connection part; and
a second protective element insertion device positioned apart from the first protective element insertion device and configured to receive the other one of the plurality of protective elements connected to the second connection part.

4. The system for mounting a protective element of a photovoltaic panel of claim 1, wherein the protective element insertion device comprises:
a body part;
a rail part configured to move the body part;
a grip part configured to grip the protective elements; and
a push part configured to push a portion of each of the protective elements in a first direction or push the protective element in a second direction that is different from the first direction.

5. The system for mounting a protective element of a photovoltaic panel of claim 4, wherein the grip part comprises:
a contact part in contact with the protective element;
a pivoting part configured to pivot the contact part; and
a pivoting driving part configured to provide driving force to the pivoting part.

6. The system for mounting a protective element of a photovoltaic panel of claim 5,
wherein the contact part comprises:
a first contact part in contact with one side of each of the protective elements; and
a second contact part in contact with another side of the protective element,
wherein the pivoting part comprises:
a first pivoting part configured to pivot the first contact part; and
a second pivoting part configured to pivot the second contact part.

7. The system for mounting a protective element of a photovoltaic panel of claim 6, wherein
the first contact part moves closer to or moves away from the second contact part.

8. The system for mounting a protective element of a photovoltaic panel of claim 7, wherein when the first contact part and the second contact part move away from each other,
the one side of the protective element maintains a state of being in contact with the first contact part, and
another side of the protective element maintains a state of being in contact with the second contact part.

9. The system for mounting a protective element of a photovoltaic panel of claim 8, wherein
as the one side of the protective element moves away from the other side of the protective element, the protective element is unfolded to correspond to the corner of the photovoltaic panel.

10. The system for mounting a protective element of a photovoltaic panel of claim 9, wherein
the push part pushes and folds a portion of an unfolded protective element.

11. The system for mounting a protective element of a photovoltaic panel of claim 9, wherein the push part comprises:
an insertion body part having a shape corresponding to the unfolded protective element; and
an insertion driving part configured to reciprocate the insertion body part in the second direction.

12. The system for mounting a protective element of a photovoltaic panel of claim 11, wherein
the insertion body part pushes a portion of the unfolded protective element to be in contact with the corner of the photovoltaic panel.

13. A method of mounting a protective element on a corner of a photovoltaic panel, the method comprising:
transporting a photovoltaic panel;
transporting, by a protective element transport device, a plurality of protective elements housed in a protective element housing device; and
inserting received protective elements into a corner of the photovoltaic panel by a protective element insertion device.

14. The method of claim 13, wherein the inserting the protective elements comprises:
a first inserting in which the protective elements are unfold to correspond to the corner of the photovoltaic panel,
a second inserting in which a portion of each of the protective elements is pushed and curved,
a third inserting in which the protective elements are transported to the corner of the photovoltaic panel and wrapped, and
a fourth inserting in which a portion of each of the protective elements is in contact with the corner of the photovoltaic panel.

15. The method of claim 14, wherein the inserting the protective elements further comprises:
folding an unfolded protective element after the first inserting.
